(19) United States
(12) Patent Application Publication
(10) Pub. No.: US 2003/0099882 A1
(43) Pub. Date: May 29, 2003

(54) Methods and materials for the preparation of a zinc anode useful for batteries and fuel cells

(76) Inventors: Mark J. Hampden-Smith, Albuquerque, NM (US); Stojan Djokic, Edmonton (CA); Paolina Atanassova, Albuquerque, NM (US); Rimple Bhatia, Placitas, NM (US); Paul Napolitano, Albuquerque, NM (US)

Correspondence Address: Marsh Fischmann & Breyfogle LLP, Suite 411, 3151 S. Vaughn Way, Aurora, CO, 80014, US

(21) Appl. No.: 10/171,079

(22) Filed: Jun. 12, 2002

Related U.S. Application Data
(60) Provisional application No. 60/297,865, filed on Jun. 12, 2001.

(51) Int. Cl. H01M 4/42; H01M 4/48; B05D 5/12; C23C 16/06; C25D 3/22

(52) U.S. Cl. 429/229; 429/231; 427/123; 427/126.3; 427/250; 205/305

(57) ABSTRACT

Methods for the deposition of zinc, particularly for the fabrication of a zinc anode that is useful in a Zn-air battery or a fuel cell. The method can be selected from electrodeposition, deposition and reduction of ZnO, physical vapor deposition and chemical vapor deposition.

### CROSS-REFERENCE TO RELATED APPLICATIONS

This application claims priority to U.S. Provisional Patent Application Serial No. 60/297,865, filed on Jun. 12, 2001, the disclosure of which is incorporated herein by reference in its entirety.

### BACKGROUND OF THE INVENTION

1. Field of the Invention

The present invention relates to methods for fabricating zinc (Zn) anodes, particularly zinc anodes that are useful in Zn-air, zinc-silver oxide, Zn/manganese oxide and zinc/nickel batteries. The present invention also relates to Zn anodes.

2. Description of Related Art

With the advent of portable and hand-held electronic devices, there is a need for high performance, economical power systems, including batteries for energy storage. Batteries can be divided into primary (non-rechargeable) and secondary (rechargeable) batteries. Common types of primary batteries include metal-air batteries such as Zn-air, Li-air and Al-air, alkaline batteries and lithium batteries. Common types of secondary batteries include nickel-cadmium, nickel metal hydride and lithium ion batteries.

One type of metal-air battery that offers many competitive advantages is the zinc-air battery, which relies upon the redox couples of O₂/OH⁻ and Zn²⁺/Zn⁰. Zinc-air batteries operate by adsorbing oxygen from the surrounding air and reducing the oxygen using an oxygen reduction catalyst at the cathode, referred to as the air electrode. As the oxygen is reduced, zinc metal is oxidized. The reactions of a zinc-air alkaline battery during discharge are:

Cathode: O₂+2H₂O+4e⁻→4OH⁻ (1)

Anode: 2Zn→2Zn²⁺+4e⁻ (2)

Overall: 2Zn+O₂+2H₂O→2Zn(OH)₂ (3)

Typically, the air electrodes are alternatively stacked with the zinc electrodes and are packaged in a container that is open to the air on the side of the air electrode. When the battery cell discharges, oxygen is reduced to O²⁻ at the cathode while zinc metal is oxidized to Zn²⁺ at the anode. Since Zn can be electrodeposited from aqueous electrolytes to replenish the anode, zinc-air batteries can be secondary batteries as well as primary batteries.

Primary (non-rechargeable) alkaline zinc-air batteries are currently used to power hearing aids and other devices that require low current densities over long periods of time. Zinc-air hearing aid batteries also include an air cathode and a zinc-based anode. The electrocatalyst powder is formed into a layer for the air cathode which catalytically converts oxygen in the air into hydroxide ion. The hydroxide ion is then transported in an alkaline electrolyte through a separator to the anode where it reacts with zinc to form zincate (Zn(OH)₄²⁻) ion and zinc ion (Zn²⁺) and liberates electrons. Among the advantages of zinc-air batteries over other battery systems are safety, long run time and light weight (i.e., high energy density). The batteries contain no toxic materials and operate at ambient pressure (e.g., one atmosphere of pressure). The light weight of zinc-air batteries leads to good power density (power per unit of weight or volume), which is ideal for portable applications.

Most zinc electrodes used in current zinc-air batteries are prepared using zinc powder, such as zinc powder that is prepared electrochemically or by thermal-atomization.

It is known that zinc powder is unstable in an aqueous alkaline solution, due to its dissolution and if air is present the corrosion accelerates considerably. The corrosion of zinc is illustrated by the following reactions (also known as self-discharge reactions):

2Zn+O₂→2ZnO (4)

Zn²⁺+2H₂O+2OH⁻→Zn(OH)₄²⁻+H₂ (5)

Reactions 4 and 5 significantly reduce shelf life of zinc-air batteries and consequently decrease the capacity of the battery and the production of electrical current.

Various approaches to improve the performance of zinc anodes and to increase the efficiency of zinc-air batteries have been disclosed. U.S. Pat. No. 4,195,120 by Rossler et al. discloses that an organic phosphate ester of the ethylene oxide adduct type can be applied to inhibit the hydrogen evolution reaction on zinc in the alkaline cells. A block of zinc alloy is used as the starting material for the electrode. This block is then melted into droplets and solidified into particles by thermal-atomization.

U.S. Pat. No. 4,112,205 by Charkoudian et al. discloses the use of double salts containing both mercuric and quaternary ammonium ions as inhibitors in galvanic cells containing NH₄Cl/ZnCl₂ electrolyte.

U.S. Pat. No. 4,084,047 by Himy et al. discloses the mixing of metal oxide inhibitors with ZnO, which exclude mercuric oxide due to the negative impact of that material on the environment. It is also disclosed that it is known to mix or alloy the active Zn in Zn/ZnO anodes and their supporting mesh (Cu or Ag structures) with 0.5 to 5.0 wt. % Hg or mercuric oxide.

U.S. Pat. No. 5,232,798 by Goldstein et al. dislcoses a method for the corrosion inhibition of zinc particulates. The zinc particulates, which were obtained electrochemically, were introduced into 30% KOH solution containing 0.4 g HgO and the mixture was stirred at 50° C. It is disclosed that corrosion inhibition can be achieved with at least one oxide selected from the oxides of Sb, Bi, Cd, Ga, In, Pb, Hg, Tl and Sn in an amount of from about 0.05 to 4.0 parts by weight, based on the weight of zinc. The zinc particulates were partially recovered from spent electrolyte of a zinc-air battery.

U.S. Pat. No. 5,419,987 by Goldstein et al. discloses a method for the preparation of zinc powder, which is used as an anode material in zinc-air batteries. The method is based on electrowinning of zinc from an alkaline solution containing 30% KOH, 40 g/L dissolved ZnO and 0.5 grams of PbO as an inhibitor. The electrolysis was carried out at 0.3 A/cm², a voltage 2.4V and a temperature of 70° C. The cathode was scraped every 2 minutes and the zinc recovered was then blended into a particulate structure. Zinc powder obtained in this way had an apparent density of about 0.2 to 2 g/cm³ and a surface area of about 0.5 to 6 m²/g. The zinc powder, alone or in combination with Bi₂O₃ and In₂O₃ showed high performance as an anode in a zinc-air battery.

U.S. Pat. No. 6,015,636 by Goldstein et al. discloses enhanced performance of zinc electrodes by mixing thermally generated zinc particles and electrochemically produced zinc particles, wherein the weight ratio of electrochemical zinc to thermally generated zinc is about 1:500.

U.S. Pat. No. 5,279,905 by Mansfield Jr. et al. discloses a process for the production of a miniature zinc-air cell having an indium plated anode. It is disclosed that the amount of mercury is reduced to less than 6%.

U.S. Pat. No. 5,863,676 by Charkey et al. discloses a Ca/Zn electrode for alkaline batteries and a method for making the electrode. The method is based on the preparation of calcium zincate material from Ca(OH)₂ and ZnO. The dry calcium zincate mixture (85%) is dry blended with additional ZnO, PbO (6 to 12%) and PTFE binder (1 to 4%). The zinc active layer is then laminated to one face of a current collector which is formed from a copper foil. The active layer includes one or more of PbO, Bi₂O₃, In₂O₃, and the like.

The effective utilization of zinc in Zn-air batteries varies from a few percent to a maximum of about 20%, especially at moderate to relatively high current densities, such as about 25 mA/cm². It would be advantageous to provide a Zn-air battery having higher effective zinc utilization. The zinc utilization will depend on different parameters including the nature of the gas-diffusion layer, the electrolyte, the surface morphology of the zinc, the surface area of the zinc and the structure of the zinc.

With the increasing demand for portable electronic devices, there is a continued need for smaller batteries to power the devices. Hence, it would be advantageous to provide a thin battery having a reduced cross-section, such as a Zn-air battery with a thickness of less than about 5 mm. One of the obstacles to fabricating a thin Zn-air battery is that presently available zinc powders for the zinc anode have an average size of from about 50 μm to 500 μm and have a non-equiaxed particle morphology. These powders are suitable for larger-traditional batteries, but are not adequate for thin batteries.

### SUMMARY OF THE INVENTION

The present invention relates to methods for fabricating zinc, especially for use as an anode in Zn-air batteries and particularly for use in thin Zn-air and other zinc electrode based battery and fuel cell systems. The thus-formed zinc anodes according to the present invention are thin and have a high effective utilization of the deposited zinc metal. Batteries having a thickness of not greater than about 5 mm can be produced.

### DESCRIPTION OF THE DRAWINGS

FIG. 1 illustrates a flowsheet for a method for making a zinc anode according to an embodiment of the present invention.

FIG. 2 illustrates an SEM photomicrograph of a ZnO powder useful for fabricating a zinc anode according to the present invention.

FIG. 3 illustrates the particle size distribution of a ZnO powder useful for fabricating a zinc anode according to an embodiment of the present invention.

FIG. 4 illustrates a ZnO powder that has been reduced to zinc in the fabrication of a zinc anode according to an embodiment of the present invention.

FIG. 5 illustrates a discharge curve for a zinc anode according to the present invention compare to a conventionally deposited zinc anode.

FIG. 6 illustrates discharge curves for zinc anodes with different additives according to the present invention.

FIG. 7 illustrates an SEM photomicrograph of zinc deposited on a printed silver current collector according to the present invention.

FIG. 8 illustrates a discharge curve for a Zn-air battery fabricated according to the present invention.

### DESCRIPTION OF THE INVENTION

The present invention relates to the deposition of zinc, particularly for the fabrication of zinc electrodes, such as for an anode in a Zn-air battery. The preferred deposition methods include physical vapor deposition (PVD), chemical vapor deposition (CVD), zinc oxide (ZnO) deposition/reduction and electrodeposition of zinc and composite zinc materials. Among these methods, electrodeposition is particularly preferred.

Thus, in one embodiment, the present invention is directed to the electrodeposition of zinc for the fabrication of the anode in a Zn-air battery. Using an electrodeposition technique, it is possible to control the fabrication process to obtain deposits with a controlled surface morphology, controlled porosity and a high surface area. High surface area is desirable to increase the utilization of the zinc in the zinc anode. Controlled porosity is needed to ensure that zinc dissolution will affect the material uniformly and will prevent structural degradation of the anode material during discharge.

Electrodeposition is the precipitation of a material (e.g., zinc) at an electrode as a result of the passage of electric current through a solution or suspension of the material. For the fabrication of a zinc anode by electrodeposition, zinc is deposited onto a conductive support. The deposited zinc that is used to construct the anode can be deposited by CVD, PVD, ZnO deposition/reduction or electrodeposition and can be deposited onto any conducting support including nickel mesh, carbon, or a printed current collector such as printed silver. The advantage of depositing the zinc or zinc alloy onto a printed current collector is that the current collector layer is then very thin, which minimizes the mass and layer thickness of the templating layer, providing for the maximum mass to be derived from zinc.

The support can be fabricated from virtually any conductive material and for thin film battery applications any metallic material with a good conductivity can be used as a support. Preferably, the metallic support can be fabricated from metals such as Ag, Au, Cu, Ni, Sn, Pb or their alloys. The structure of the support can be the in the form of, for example, a wire or metallic foam, or can be deposited on a ceramic or plastic substrate by printing (e.g., screen printing), electroless deposition, electrodeposition, CVD or PVD.

For electrodeposition, the support is placed in an electrolytic bath. The electrolytic bath includes a zinc source such as zinc sulfate (ZnSO₄) or zinc chloride (ZnCl₂). In a preferred embodiment, a combination of zinc sulfate and zinc chloride is used. Other additives to the electrolytic bath can include buffers such as H₃BO₄.

In a particular preferred embodiment, the electrolytic bath also includes a bismuth source, such as bismuth nitrate (Bi(NO₃)₃). The incorporation of bismuth advantageously produces a zinc deposit having an increased surface area as compared to zinc deposited without bismuth. Preferably, bismuth is included in the electrolytic bath in an amount of from about 1 wt. % to about 2 wt. %. Other additives can include lead (Pb), indium (In), cadmium (Cd), mercury (Hg) and tin (Sn), in elemental or compound form. Additives adapted to suppress hydrogen evolution can also be utilized.

The support is placed in the bath and a current density is maintained in the bath for a period of time sufficient to develop the zinc anode. In one preferred embodiment, a current density of from about 20 A/cm² to about 250 A/cm² is maintained in the bath. The time period can be, for example, from about 1 minute to about 8 hours, depending on the desired properties such as surface morphology, density and porosity.

The average thickness of the layer of electrodeposited zinc forming the anode is preferably not greater than about 5000 μm and more preferably is not greater than about 3000 μm. In one embodiment, the average thickness is from about 50 μm to about 5000 μm, such as from about 50 μm to about 3000 μm. In one embodiment, the average thickness is from about 50 μm to about 1500 μm, such as from about 250 μm to about 1500 μm. For some applications, the layer of electrodeposited zinc can be very thin, such as not greater than about 200 μm in average thickness.

According to another embodiment of the present invention, a zinc layer is deposited by printing, such as by screen printing. According to this embodiment, zinc oxide (ZnO) particles are deposited and are then reduced to zinc metal. The properties of the zinc oxide are controlled to enable control over the properties of the zinc metal, such as the particle size, surface area and porosity of the zinc. A preferred method for fabricating the zinc oxide particles is a spray pyrolysis or spray conversion method, such as that disclosed in U.S. Pat. No. 6,180,029 by Hampden-Smith et al. which is incorporated herein by reference in its entirety.

For thin battery applications it is preferred that the average particle size of the zinc oxide is within the range of from about 1 μm to 250 μm, and it is more preferred that the average particle size is not greater than 50 μm. The resulting printed film thickness, depending on the projected applications and particle size, may vary from about 10 μm to about 3000 μm, such as from about 200 μm to about 1000 μm.

The zinc paste composition (printing composition) can include other additives such as alginic acid or sodium alginate, preferably in an amount of from about 2 wt. % to about 4 wt. %. These additives assist in the complexing of the zinc and ensure that the zinc oxide that forms reacts to form a soluble salt such as zinc alginate. Materials such as carboxyl methyl cellulose (CMC) can also be added. Further, a tetrafluoroethylene fluorocarbon polymer such as TEFLON (E.I. duPont deNemours Corp., Wilmington, Del.) can be added to the paste composition. Such polymers help bind the system together and adjust the hydrophobicity of the material.

Other additives to the printing composition can include oxides such as Bi₂O₃, PbO and HgO. Such additives are preferably added in an amount of not greater than about 2 wt. % of the printing composition. Preferably, the printing composition includes at least about 80 wt. % ZnO, such as from about 80 wt. % to about 92 wt. % ZnO.

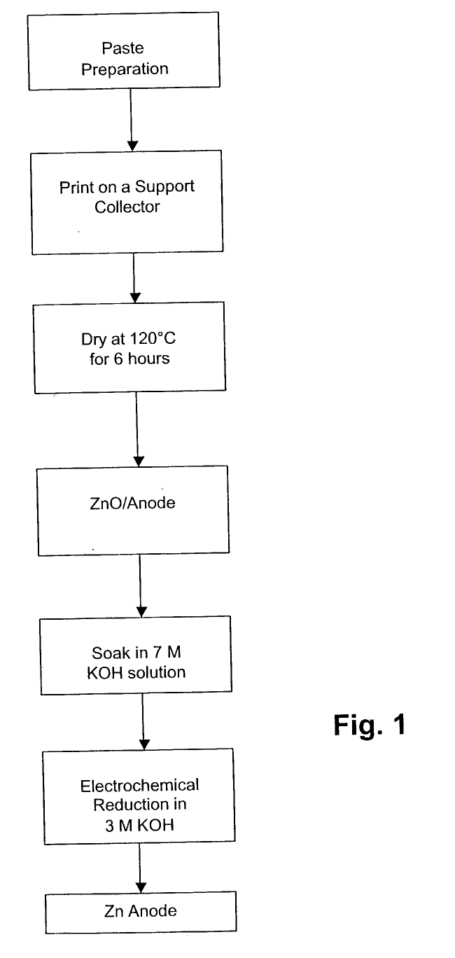

After printing, the deposited layer is dried at room temperature, such as for at least about 4 hours and is then dried in an oven, such as at a temperature of about 125° C. for about 6 hours. The zinc electrode can then be prepared by reducing the zinc oxide to zinc metal. For example, the zinc oxide layer deposited on the support can be soaked in a KOH solution (e.g., about 7 M KOH) for about 5 hours. The assembly can then be placed in an electrochemical cell in order to reduce ZnO to Zn metal. After the reduction, electrodes are ready for the use as anodes in the zinc-air batteries or other battery configurations with a zinc electrode. This process is schematically illustrated in FIG. 1.

The average thickness of the layer formed by deposition and reduction of zinc oxide is preferably not greater than about 3000 μm. In one embodiment, the average thickness is from about 50 μm to about 3000 μm and more preferably is from about 50 μm to about 1500 μm. For some applications, the layer of zinc can be very thin, such as not greater than about 200 μm in average thickness.

In addition to the foregoing, zinc can be deposited by chemical vapor deposition (CVD) or physical vapor deposition (PVD).

When the zinc is deposited in accordance with the present invention, the zinc anode can have an effective utilization of at least about 40 percent, such as from about 40 percent to about 60 percent, such as when used in a thin film battery.

### EXAMPLES

### Example 1

### Comparative Example

A zinc anode was prepared using zinc powder (containing 3 wt. % Hg as an additive to control the reaction between zinc and electrolyte), carboxymethylcellulose (CMC), alginic acid and a suspension of PTFE (60% solid particles) based on the following formulation:

TABLE 1

| Component | Amount | |
|---|---|---|
| Zn Powder | 90 | g |
| CMC | 4 | g |
| Sodium Alginate | 3 | g |
| PTFE | 3 | g |
| PbO | 0.5 | g |
| Bi₂O₃ | 0.3 | g |

The Zn powder, CMC, sodium alginate, PbO and Bi₂O₃ were wetted with ethanol and 10 mL of a 7 M KOH aqueous solution was added. The slurry was mixed with an additional 20 mL of water. The PTFE suspension was added to this slurry and stirring was continued in order to homogenize the slurry. After homogenization, the slurry was filtered.

The dough obtained in this way was used to form an electrode on a Ni-mesh current collector. The dough was rolled into a 0.5 mm sheet and a pressure of about 150 kg/cm² was applied. The electrode obtained in this way was dried at room temperature for 6 hours and then was dried in an oven at 125° C. for 2 hours. The anode prepared in this way was utilized in a prismatic zinc-air cell.

### Example 2

### Printing Methodology

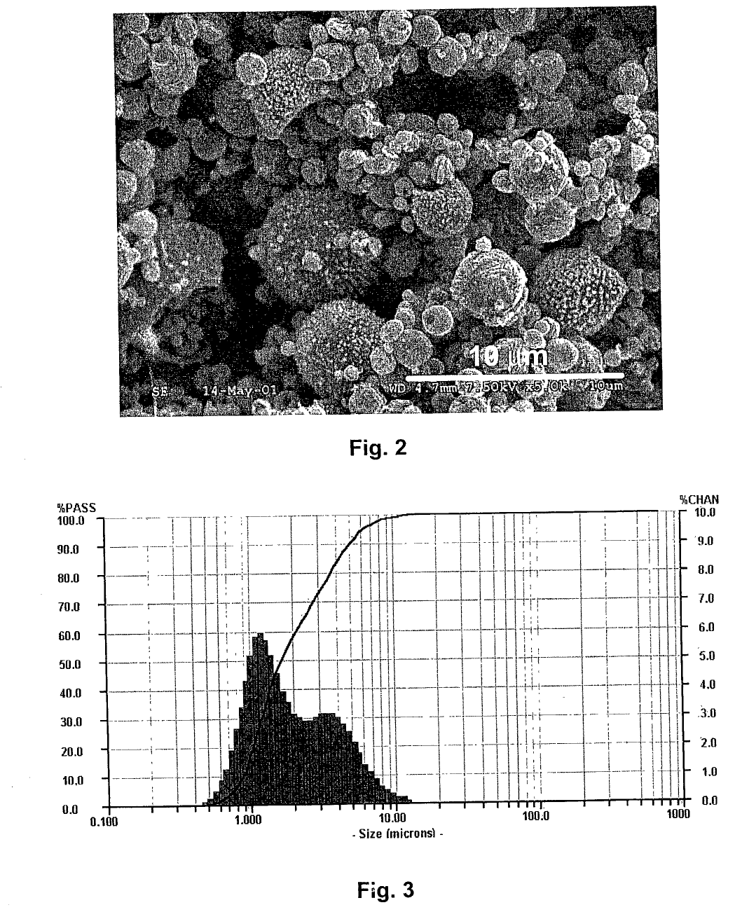

According to one embodiment of the present invention, a zinc anode can be formed by depositing zinc oxide (ZnO) particles and reducing the particles to zinc metal. The ZnO powder can be fabricated by spray pyrolysis. An SEM photomicrograph of a ZnO fabricated by spray pyrolysis is illustrated in FIG. 2. The particle size distribution for this powder is illustrated in FIG. 3. The volume average particle size (d₅₀) was 2.5 μm.

A ZnO dough was made according to the following formulation and procedure as described below.

TABLE 2

| Component | Amount | |
|---|---|---|
| ZnO Powder | 45 | g |
| CMC | 2 | g |
| Sodium Alginate | 2 | g |
| PTFE | 2 | g |
| PbO | 0.3 | g |
| Bi₂O₃ | 0.2 | g |

A dry mixture of ZnO powder, CMC, sodium alginate powder, PbO and Bi₂O₃ was wetted with ethanol and then homogenized with water. A suspension of PTFE was added to this mixture and mixing was continued. For the separation of a sufficient amount of water, vacuum filtration was applied. The dough was rolled into a sheet with 0.5 mm in thickness and then pasted into a nickel mesh current collector. After drying at room temperature for at least 24 hours, samples were dried in an oven at 125° C. for 4 hours.

The dried samples were electrolyzed in a 4M KOH solution at a constant current of 0.08 A/cm² and a voltage of about 3.5V for about 2 hours. In this example, the ZnO pasted electrode served as a cathode in order to reduce ZnO to Zn, according to the reaction:

ZnO+H₂O+2e⁻→Zn+2OH⁻ (6)

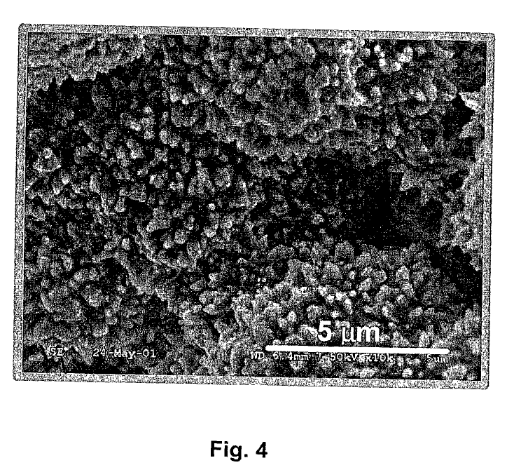

Ni mesh was used as an anode. XRD analysis confirmed reduction of ZnO into Zn. The zinc anode prepared in this way was introduced in a prismatic zinc cell as described in the Example 1. The open circuit potential of the zinc electrode was stable for over 48 hours and it was about −1.4 V. An SEM photomicrograph of the zinc formed by the deposition and reduction of zinc oxide is illustrated in FIG. 4.

### Example 3

### Electrodeposition Method

In order to produce a Zn electrode for thin film battery (TFB) applications, zinc was electrodeposited from a solution with the following composition.

TABLE 3

| Component | Amount | |
|---|---|---|
| ZnSO₄ | 180 | g/L |
| ZnCl₂ | 14 | g/L |
| H₃BO₃ | 12 | g/L |
| Bi(NO₃)₃ | 2 | g/l |

The pH was from about pH 2.5 to pH 4.5. The electrodeposition of zinc was carried out at 0.2 A/cm² for 2 hours. An estimated thickness of the deposited zinc film was about 100 μm. The zinc anode prepared in this way was introduced in a prismatic zinc cell as is described in Example 1. The open circuit potential of the zinc electrode was stable for over 48 hours and it was about −1.4 V.

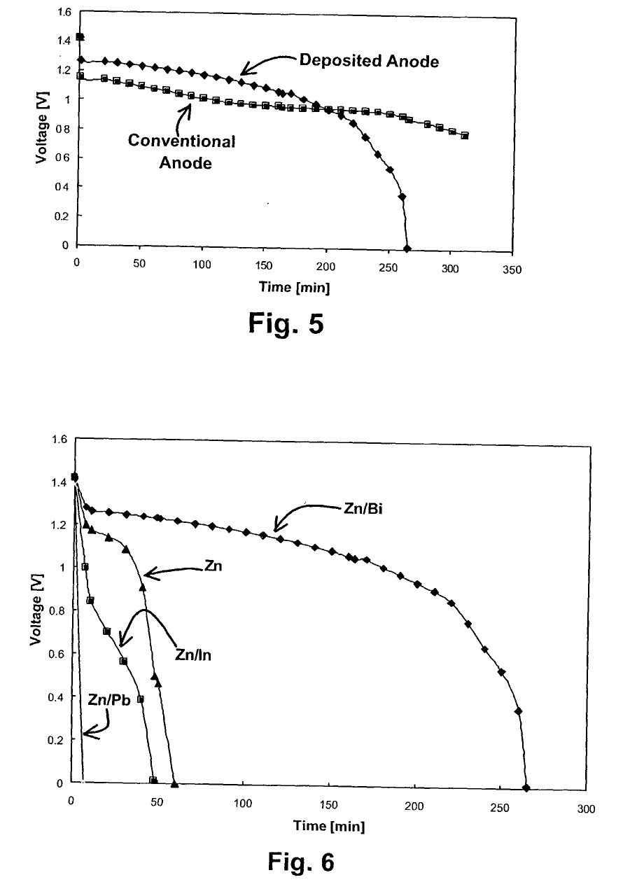

FIG. 5 illustrates a discharge curve at for the zinc anode deposited in accordance with Example 3 compared to zinc anode that was deposited in accordance with Example 1.

### Example 4

Four different compositions of electrodeposited zinc were prepared, each with a different additive, and were tested in a Zn-air battery. The results are listed in Table 4. The results are also shown graphically in FIG. 6 which illustrates the voltage over time at a current of 50 mA.

TABLE 4

| | | m′ | | | |
|---|---|---|---|---|---|
| | | Exposed to | | m″ | |
| Additive | m | Electrolyte | Q | Dissolved | Efficiency |
| to Zn | (g/cm²) | (g) | (C) | (Faraday's Law) | (%) |
| Bi | 0.04503 | 0.3062 | 750 | 0.25414 | 83 |
| | | 0.72048 | | | 35 |
| In | 0.00985 | 0.131005 | 45 | 0.0124 | 12 |
| Pb | 0.00242 | 0.0884216 | 15 | 0.05109 | 29 |
| None | 0.00932 | 0.1237 | 135 | 0.0457 | 37 |

Referring to Table 4: m is the mass of zinc deposited as determined by mass increase during the electrodeposition experiments; m′ (exposed to electrolyte) is the mass of zinc exposed to electrolyte; Q is the charge calculated from the discharge of the battery; and m″ (dissolved) is the mass of zinc used, as calculated from the amount of charge passed. Discharge data measured at 50 mA for each sample are illustrated in FIG. 6.

### Example 5

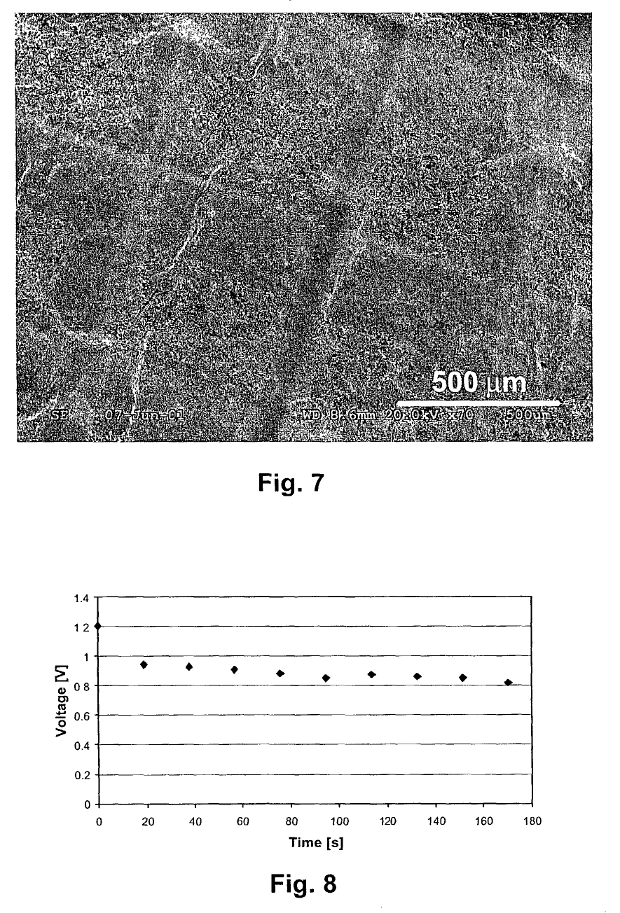

A silver current collector that had been deposited onto a gas diffusion layer was used as the substrate for a zinc deposition experiment. In accordance with the foregoing, the silver current collector was immersed half way into the deposition bath and the zinc deposited on the silver to the point where it was immersed into the bath. FIG. 7 illustrates an SEM photomicrograph of the interface region between deposition and no deposition, with deposition of Zn clear at the interfacial region.

In another experiment, a nickel mesh current collector was used as a substrate upon which zinc was deposited. This nickel mesh current collector was then used to construct a very small battery with lateral dimensions of a few mm×a few mm. The discharge curve for this battery is illustrated in FIG. 8.

While various embodiments of the present invention have been described in detail, is apparent that modifications and adaptations of those embodiments will occur to those skilled in the art. However, is to be expressly understood that such modifications and adaptations are within the spirit and scope of present invention.

What is claimed is:

1. A method for making a zinc anode, wherein said zinc anode is produced by a method selected from the group consisting of electrodeposition, printing of zinc oxide, physical vapor deposition and chemical vapor deposition.

2. A method for making a zinc anode as recited in claim 1, wherein said zinc anode has an average thickness of not greater than about 3000 μm.

3. A method for making a zinc anode as recited in claim 1, wherein said zinc anode has an average thickness of not greater than about 200 μm.

4. A method for making a zinc anode as recited in claim 1, wherein said method comprises depositing zinc oxide powder on a support and reducing said zinc oxide powder to zinc metal.

5. A method for making a zinc anode as recited in claim 4, wherein said method comprises printing of said zinc oxide powder on said support using a printing composition, said printing composition further comprising carboxyl methyl cellulose, alginic acid, fluorcarbon polymer and at least a first additive selected from the group consisting of Bi₂O₃, PbO and HgO.

6. A method for making a zinc anode as recited in claim 4, wherein said printing step comprises printing with a paste comprising zinc oxide in an amount of from about 80 wt. % to about 92 wt. %.

7. A method for making a zinc anode as recited in claim 4, wherein said printing step comprises printing with a paste composition comprising carboxyl methyl cellulose and alginic acid in an amount of from about 2 wt. % to about 4 wt. %.

8. A method for making a zinc anode as recited in claim 4, wherein said printing step comprises printing with a paste comprising not greater than about 2 wt. % of additives selected from the group consisting of Bi₂O₃, PbO and HgO.

9. A method as recited in claim 1, wherein said zinc anode is adapted for use in a thin film battery.

10. A method for making a zinc anode adapted for use in a thin film battery, wherein said zinc anode is produced by electrodeposition of zinc onto a support.

11. A method for making a zinc anode as recited in claim 10, wherein said zinc anode has an average thickness of not greater than about 3000 μm.

12. A method for making a zinc anode as recited in claim 10, wherein said zinc anode has an average thickness of not greater than about 200 μm.

13. A method for making a zinc anode as recited in claim 10, wherein said zinc anode is electrodeposited from an electrolyte comprising a zinc source selected from the group consisting of zinc sulfate, zinc chloride and mixtures thereof.

14. A method for making a zinc anode as recited in claim 10, wherein said zinc anode is electrodeposited from an electrolyte comprising at least at first additive adpated to suppress hydrogen evolution.

15. A method for making a zinc anode as recited in claim 10, wherein said zinc anode is electrodeposited from an electrolyte comprising an additive selected from the group consisting of Pb, Bi, In, Cd, Hg and Sn.

16. A method for making a zinc anode as recited in claim 10, wherein said zinc anode is electrodeposited from an electrolyte comprising a zinc source selected from the group consisting of zinc sulfate, zinc chloride and mixtures thereof and further comprising a source of bismuth.

17. A method for making a zinc anode as recited in claim 10, wherein said anode has an average thickness of from about 50 μm to about 5000 μm.

18. A method for making a zinc anode as recited in claim 10, wherein said anode has an average thickness of from about 250 μm to about 1500 μm.

19. A method for making a zinc anode as recited in claim 10, wherein said zinc anode is deposited on a current collector selected from the group consisting of conductive wires, foams, printed metallic structures onto ceramic or plastic substrates, electroless deposited, electrodeposited, CVD, PVD metallic films or structures on plastic and ceramic substrates.

20. A method for making a zinc anode as recited in claim 10, wherein said zinc anode has an effective utilization in a thin film battery of at least about 40 percent.

21. A method for making a zinc anode as recited in claim 10, wherein said zinc anode has an effective utilization in a thin film battery of from about 40 percent to about 60 percent.

22. A zinc electrode comprising zinc metal deposited by a method selected from the group consisting of electrodeposition, printing of zinc oxide, physical vapor deposition and chemical vapor deposition.

23. A zinc electrode as recited in claim 22, wherein said zinc electrode has an average thickness of not greater than about 3000 μm.

24. A zinc electrode as recited in claim 22, wherein said zinc electrode has an average thickness of not greater than about 200 μm.

25. A zinc electrode as recited in claim 22, wherein said method is electrodeposition.

26. A zinc electrode as recited in claim 22, wherein said zinc electrode is an anode.
